(19) United States
(12) Patent Application Publication
(10) Pub. No.: US 2025/0308996 A1
(43) Pub. Date: Oct. 2, 2025

(54) SEMICONDUCTOR STRUCTURE WITH INCREASED DENSITY OF ELECTRICAL CONDUCTIVE PATHS AND METHOD FOR MANUFACTURING THE SAME

(71) Applicant: TAIWAN SEMICONDUCTOR MANUFACTURING COMPANY, LTD., Hsinchu (TW)

(72) Inventors: Shu-Wei LI, Hsinchu (TW); Chuan-Pu CHOU, Hsinchu (TW)

(73) Assignee: TAIWAN SEMICONDUCTOR MANUFACTURING COMPANY, LTD., Hsinchu (TW)

(21) Appl. No.: 18/624,564

(22) Filed: Apr. 2, 2024

(51) Int. Cl. H01L 21/768; H01L 23/522; H01L 23/532

(52) U.S. Cl. CPC H01L 21/76885; H01L 21/76832; H01L 21/76834; H01L 23/5226; H01L 23/53209; H01L 23/53276; H01L 23/53295

(57) ABSTRACT

A method for manufacturing an interconnecting structure includes: forming first conductive portions on a base structure, the first conductive portions being spaced apart from each other; after forming the first conductive portions, forming insulating portions which are spaced apart from each other to respectively cover the first conductive portions; and after forming the insulating portions, forming second conductive portions on the base structure such that the second conductive portions are disposed to alternate with the first conductive portions and such that each of the first conductive portions is separated from two adjacent ones of the second conductive portions through a respective one of the insulating portions.

### BACKGROUND

With rapid development of semiconductor technology, for a back-end interconnecting structure, width of metal lines therein is getting smaller, and pattern density of the metal lines is getting higher. The size miniaturization of the metal lines is getting harder to achieve due to limitations in patterning techniques. In the back-end interconnecting structure with high pattern density, prevention of current leakage between two adjacent metal lines becomes more important. Therefore, methods for manufacturing the back-end interconnecting structure with high pattern density and low current leakage are being continuously developed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow diagram illustrating a method for manufacturing an interconnecting structure in accordance with some embodiments.

FIGS. 2 to 16 are schematic views illustrating intermediate stages of the method depicted in FIG. 1 in accordance with some embodiments.

FIGS. 17 to 24 are schematic views illustrating intermediate stages of the method depicted in FIG. 1 in accordance with certain embodiments.

FIGS. 25 to 27 are schematic sectional views illustrating a semiconductor structure including the interconnecting structure in accordance with some other embodiments.

FIG. 28 is a schematic perspective view illustrating the interconnecting structure in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “top,” “bottom,” “upper,” “lower,” “over,” “beneath,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For the purposes of this specification and appended claims, unless otherwise indicated, all numbers expressing amounts, sizes, dimensions, proportions, shapes, formulations, parameters, percentages, quantities, characteristics, or other numerical values used in the specification and claims, are to be understood as being modified in all instances by the terms “about” and “substantially” even if the terms “about” and “substantially” are not explicitly recited with the values, amounts or ranges. Accordingly, unless indicated to the contrary, the numerical parameters set forth in the following specification and appended claims are not and need not be exact, but may be approximations and/or larger or smaller than specified as desired, may encompass tolerances, conversion factors, rounding off, measurement error, and other factors known to those of skill in the art depending on the desired properties sought to be obtained by the presently disclosed subject matter. For example, the terms “about” and “substantially,” when used with a value, can capture variations of, in some aspects+10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions.

The term “source/drain portion(s)” may refer to a source or a drain, individually or collectively dependent upon the context.

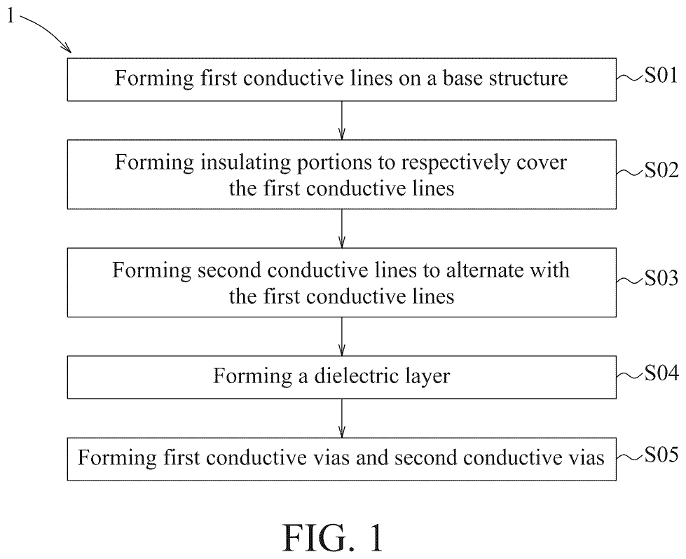

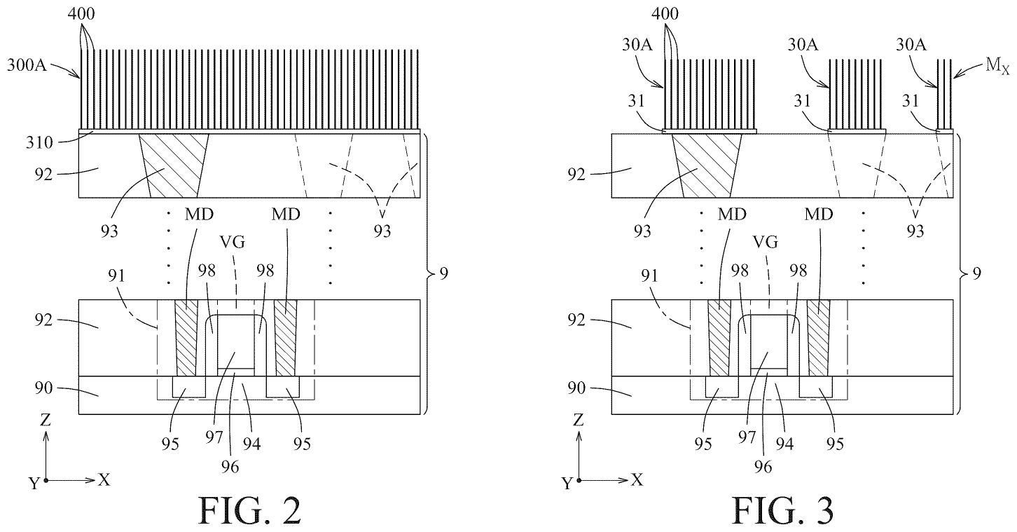

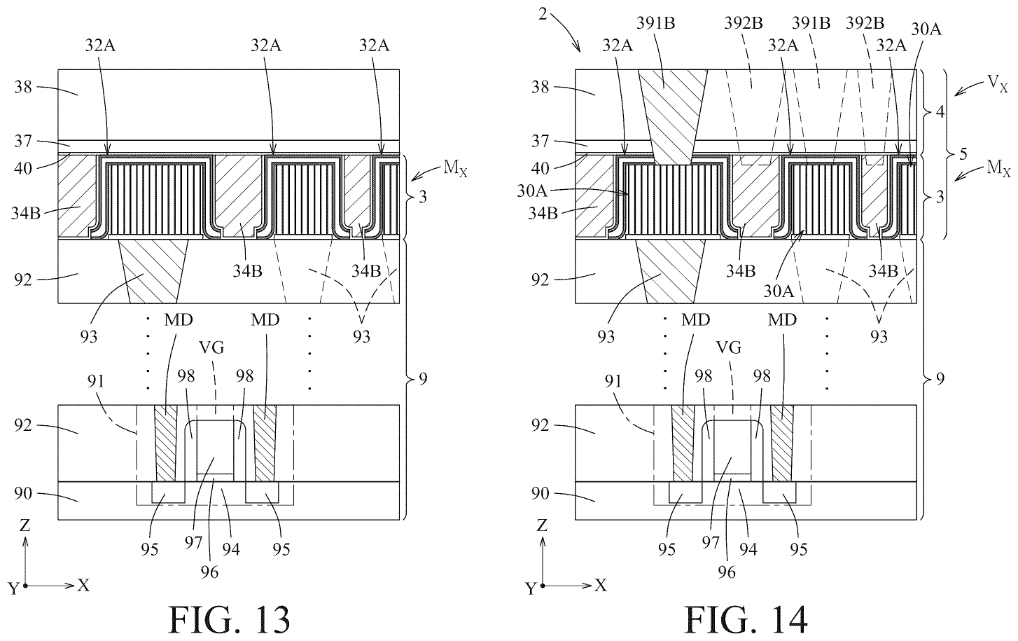

FIG. 1 is a flow diagram illustrating a method 1 for manufacturing an interconnecting structure (e.g., the interconnecting structure 5 shown in FIG. 14, 16, 22, 24, 25, 26 or 27) in a semiconductor structure 2 in accordance with some embodiments. The method 1 may include steps S01 to S05. FIGS. 2 to 16 are schematic views illustrating intermediate stages of the method 1 in accordance with some embodiments.

Referring to FIG. 1 and the example illustrated in FIG. 3, the method 1 begins at step S01, where first conductive lines 30A (which may be also referred to as first conductive portions) are formed on a base structure 9. In some embodiments, the first conductive lines 30A may be located at any one of metal levels Mₓ, where x may be 0 or an integer not less than 1. FIG. 2 is a schematic view illustrating a sub-step of step S01, in which the first conductive lines 30A are formed in accordance with some embodiments.

In some embodiments, as shown in FIG. 3, the first conductive lines 30A are spaced apart from each other in an X direction and elongated in a Y direction transverse to the X direction. In some embodiments, widths of the first conductive lines 30A in the X direction may be the same as or different from each other.

Each of the first conductive lines 30A includes a two-dimensional (2d) conductive material. The 2d conductive material has a multi-layered structure and a 2d conducting path. That is, the electrical conductivity of each of the first conductive lines 30A is non-isotropic. In the multi-layered structure of the 2d conductive material, the electrical conductivity along a layer (plane) where atoms of the 2d conductive material are connected to each other is relatively high, and the electrical conductivity among the different layers or planes which are stacked on each other is relatively low. For example, for each of the first conductive lines 30A, the electrical conductivity along the X direction is much less than the electrical conductivity along directions other than the X direction. In some embodiments, the 2d conductive material includes graphene, 2d metal, 2d alloy, or 2d transition metal dichalcogenide. The 2d metal includes a single metal element, and the 2d alloy includes at least two metal elements. In some embodiments, metal elements suitable for forming the 2d metal (or 2d alloy) includes Al, Fe, Co, Ni, Cu, Ru, Rh, Pd, Ag, Sn, Sb, Ir, Pt, Au, Pb, Bi, or combinations thereof. In some embodiments, the transition metal dichalcogenide includes a transition metal (e.g., Zr, Ta, Nb, W, Mo, Ga, Sn, etc.) and a chalcogenide (e.g., Se, S, Te, etc.). It is noted that the electronic properties of the 2d transition metal dichalcogenide is quite different from the electronic properties of a bulk transition metal dichalcogenide. For example, although the bulk transition metal dichalcogenide serving as a semiconductor material has a relatively low electrical conductivity, the electrical conductivity of the 2d transition metal dichalcogenide is high enough to allow the 2d transition metal dichalcogenide to be formed as conductive lines (e.g., the first conductive lines 30A) in an interconnecting structure. Other suitable 2d conductive materials are within the contemplated scope of the present disclosure.

As shown in FIG. 3, each of the first conductive lines 30A may include a plurality of monolayers 400 of the 2d conductive material (such as the examples described in the previous paragraph). For example, in the case that each of the conductive lines 30A is made of graphene, each of the monolayers 400 is a single layer of carbon atoms arranged in a hexagonal lattice nanostructure. In some embodiments, the monolayers 400 are stacked on each other in the X direction, and the carbon atoms in each of the monolayers 400 are connected to each other in an YZ plane defined by the Y direction and a Z direction transverse to the X and Y directions. In some embodiments, two adjacent ones of the monolayers 400 may be brought together by intermolecular force, for example, but not limited to, van der Waals force. In some embodiments, the X, Y and Z directions are perpendicular to each other. As shown in FIG. 3, in each of the first conductive lines 30A, the electrical conductivity is relatively high in each of the monolayers 400, while the electrical conductivity between two adjacent ones of the monolayers 400 is relatively low.

In some embodiments, in step S01, underlying portions 31 are formed on the base structure 9 such that the first conductive lines 30A are formed on the underlying portions 31, respectively. In some embodiments, the underlying portions 31 are provided to improve adhesion of the first conductive lines 30A to the base structure 9, or to facilitate bottom-up growth of the 2d conductive material of the first conductive lines 30A. In some embodiments, the underlying portions 31 may include titanium nitride, silicon, Bi₂Te₃, SiC, or Pd. In some embodiments, each of the underlying portions 31 may have a thickness ranging from about 0.3 nm to about 10 nm, but is not limited thereto. In the case that the first conductive lines 30A are made of 2d Ga, the underlying portions 31 are made of silicon with (111) plane for growing 2d Ga. In the case that the first conductive lines 30A are made of 2d Sn, the underlying portions 31 are made of Bi₂Te₃ with (111) plane for growing 2d Sn. In the case that the first conductive lines 30A are made of Bi, the underlying portions 31 are made of SiC with (0001) plane for growing Bi. In the case that the first conductive lines 30A are made of Sb with (111) plane, InSb with (111) plane, Cu with (111) plane, or Pb, the underlying portions 31 are made of Pd with (111) plane for growing Sb with (111) plane, InSb with (111) plane, Cu with (111) plane, or Pb. Other possible materials suitable for the underlying portions 31 are within the contemplated scope of the present disclosure.

In some embodiments, step S01 may include two sub-steps, which are sequentially shown in FIGS. 2 and 3.

Referring to FIG. 2, in the first sub-step, an underlying layer 310 (which may be also referred to as an adhesion layer or a seed layer) and a first conductive layer 300A are sequentially formed on the base structure 9. The underlying layer 310 includes the material of the underlying portions 31 (see FIG. 3). The first conductive layer 300A includes the material of the first conductive lines 30A (see FIG. 3). Hence, the first conductive layer 300A includes the monolayers 400 of the 2d conductive material. In some embodiments, the underlying layer 310 may be formed by atomic layer deposition (ALD), physical vapor deposition (PVD), chemical vapor deposition process (CVD), or other suitable deposition techniques. In some embodiments, the first conductive layer 300A may be formed by thermal CVD, plasma-enhanced CVD (PECVD), a dry transfer printing technique, or other suitable deposition techniques. In the case that the first conductive layer 300A is formed by the dry transfer printing technique, the 2d conductive material may be transferred from a growth substrate onto the underlying layer 310 (which may be referred to as a target substrate) utilizing a conformable transfer film such as an elastomeric stamp.

Referring to FIG. 3, in the second sub-step, a patterning process is performed such that the first conductive layer 300A (see FIG. 2) is formed into the first conductive lines 30A, and the underlying layer 310 (see FIG. 2) is formed into the underlying portions 31. In some embodiments, the patterning process may include a photolithography process.

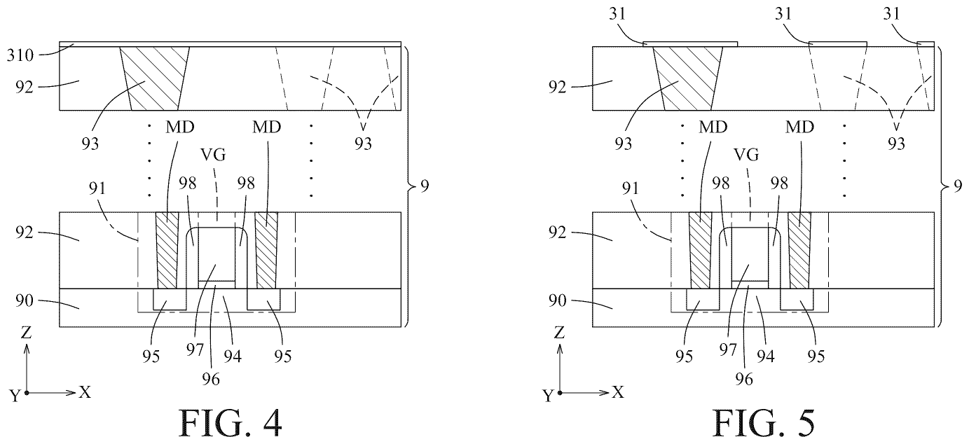

In some alternative embodiments, FIGS. 4 and 5 are schematic views illustrating intermediate stages of step S01, and step S01 may include three sub-steps, which are sequentially shown in FIGS. 4, 5 and 3.

In the first sub-step, referring to FIG. 4, the underlying layer 310 is formed on the base structure 9 by ALD, PVD, CVD, or other suitable deposition techniques.

In the second sub-step, referring to FIG. 5, a patterning process is performed such that the underlying layer 310 (see FIG. 4) is formed into the underlying portions 31 and such that portions of the base structure 9 are exposed from the underlying portions 31.

In the third sub-step, referring to FIG. 3, with the provision of the underlying portions 31, the first conductive lines 30A are selectively formed on the underlying portions 31, respectively, and are less likely to be formed on the base structure 9. Thus, the portions of the base structure 9 (which are exposed from the underlying portions 31 shown in FIG. 5) may be still exposed from first conductive lines 30A. In some embodiments, after selective formation of the first conductive lines 30A, an etching process may be performed to remove the 2d conductive material which are undesirably deposited on the portions of the base structure 9.

In some embodiments, after step S01, each of the underlying portions 31 has two side surfaces which are opposite to each other in the X direction and which are exposed from a respective one of the first conductive lines 30A located thereabove.

In some embodiments, the base structure 9 may include a substrate 90, a semiconductor device 91 formed on the substrate 90 during a front-end-of-line fabrication procedure, inter-layer dielectric (ILD) layers 92 formed to cover the semiconductor device 91, source/drain contacts (MD) and a gate contact (VG) formed in a lowermost one of the ILD layers 92, and conductive elements 93 formed in an uppermost one of the ILD layers 92. In some embodiments, the semiconductor device 91 may be a field-effect transistor (FET), and includes a channel 94, two source/drain portions 95 formed at two opposite sides of the channel 94, a gate dielectric layer 96 formed on the channel 94, a gate electrode 97 formed on the gate dielectric layer 96 such that the channel 94 is spaced apart from the gate electrode 97 by the gate dielectric layer 96, and two dielectric spacers 98 respectively formed at two opposite sides of the gate electrode 97. In some embodiments, the source/drain contacts (MD) are respectively formed on the source/drain portions 95, and the gate contact (VG) is formed on the gate electrode 97. In some embodiments not shown herein, the base structure 9 further includes via contacts (VD, not marked in figures) which are respectively formed on the source/drain contacts (MD). In the case that the first conductive lines 30A are located at the metal level Mo, each of the first conductive lines 30A may be directly connected to a corresponding one of the via contacts (VD) and the gate contact (VG) (i.e., the via contacts (VD) and the gate contact (VG) respectively serve as the conductive elements 93 which are not drawn in scale). In the case that the first conductive lines 30A are located at the metal level M₂, the first conductive lines 30A may be connected to inter-metal vias (IVs) which are located at a via level V₁ beneath the metal level M₂ and which serve as the conductive elements 93, respectively. In some embodiments, the semiconductor device 91 may be configured as a planar FET, in which (i) the source/drain portions 95 are formed in the substrate 90 by an implantation process, and (ii) a portion of the substrate 90, which is located between the source/drain portions 95, serves as the channel 94. The source/drain portions 95 may be doped with impurities so as to have an n-type conductivity or a p-type conductivity according to the type of the first semiconductor device 91 (i.e., the source/drain portions 95 have the n-type conductivity when the first semiconductor device 91 is an n-FET; and the source/drain portions 95 have the p-type conductivity when the first semiconductor device 91 is a p-FET). In some embodiments, the gate dielectric layer 96 may be made of silicon oxide, and the gate electrode 97 may be made of polycrystalline silicon. In some other embodiments not shown herein, the first semiconductor device 91 may be configured as a fin-type field-effect transistor (FinFET), or a gate-all-around field-effect transistor (GAAFET). In such case, the gate dielectric layer 96 may include a high dielectric constant (high-k) material, and the gate electrode 97 include a work function metal. In some other embodiments not shown herein, the semiconductor device may be configured as a complementary field-effect transistor (CFET) which includes two GAAFETs stacked on one another in the Z direction, a fork-sheet structure which includes two GAAFETs spaced part from each other in the Y direction through a wall portion, or other suitable three-dimensional (3d) transistors. In some embodiments, the number of the semiconductor device 91 is not limited to one, as shown in FIG. 3, and may vary according to practical applications. Other possible materials suitable for the elements in the base structure 9 are within the contemplated scope of the present disclosure.

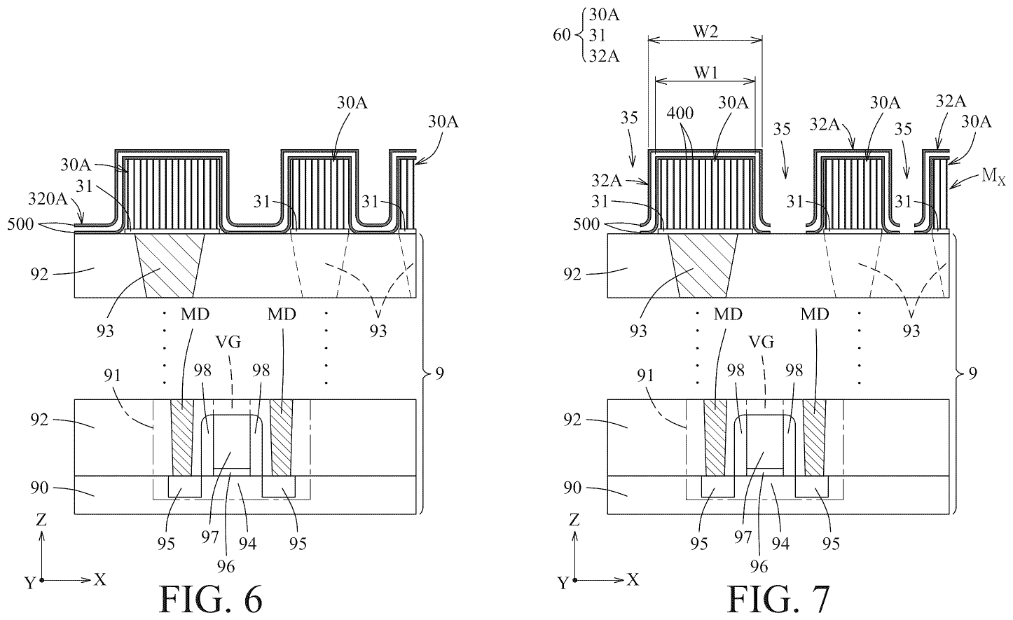

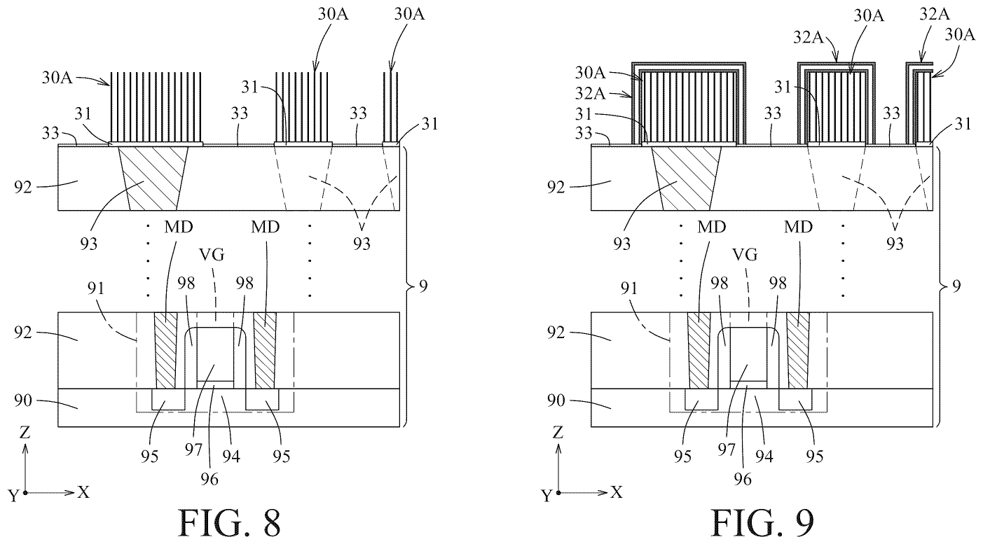

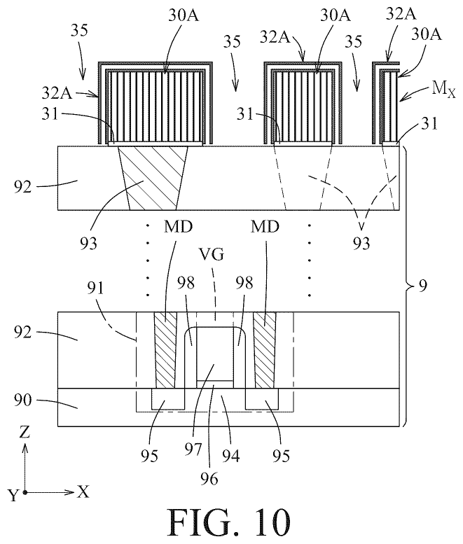

Referring to FIG. 1 and the examples illustrated in FIGS. 7 and 10, the method 1 proceeds to step S02, where insulating portions 32A are formed to respectively cover the first conductive lines 30A, and trenches 35 are formed to alternate with the insulating portions 32A. The insulating portions 32A are spaced apart from each other. Each of the trenches 35 is bordered by the base structure 9 and two corresponding adjacent ones of the insulating portions 32A. FIGS. 7 and 10 are each a schematic sectional view similar to that of FIG. 3, but illustrating the structure after step S02 in accordance with different embodiments. FIG. 6 is a schematic view illustrating a sub-step of step S02, in which the insulating portions 32A shown in FIG. 7 are formed in accordance with some embodiments, whereas FIGS. 8 and 9 are schematic views illustrating sub-steps of step S02, in which the insulating portions 32A shown in FIG. 10 are formed in accordance with some alternative embodiments.

In some embodiments, as shown in FIG. 7, each of the insulating portions 32A is further formed to cover the side surfaces of a respective one of the underlying portions 31 located therebeneath. Each of the insulating portions 32A includes a 2d insulating material. The 2d insulating material has a layered structure in which atoms are firmly bonded together in each layer and two adjacent layers are held together by a relatively weak force (e.g., an intermolecular force). In some embodiments, the 2d insulating material includes hexagonal boron nitride (h-BN), 2d hafnium oxide, or 2d CaF₂. In some embodiments, as shown in FIG. 7, each of the insulating portions 32A may include two monolayers 500 of the 2d insulating material (such as the examples described above) stacked on each other. In some embodiments not shown herein, the number of the monolayers 500 in each of the insulating portions 32A may be about one, or may range from about 3 to about 100. Other suitable 2d insulating materials are within the contemplated scope of the present disclosure.

In some embodiments, as shown in FIG. 7, the monolayers 500 in each of the insulating portions 32A conformally cover the respective the first conductive line 30A. In other words, in each of the insulating portions 32A, an outer one of the monolayers 500 is stacked on an inner one of the monolayers 500 opposite to the respective first conductive line 30A. In some embodiments, each of the insulating portions 32A includes two vertical regions located at two opposite sides of the respective first conductive line 30A, and a horizontal region which is located above the respective first conductive line 30A and which interconnects the two vertical regions. In some embodiments, the monolayers 500 located at each of the vertical regions are arranged substantially parallel to the monolayers 400. That is, at each of the vertical regions, the monolayers 500 are stacked on each other in the X direction, and atoms in each of the monolayers 500 are connected to each other in the YZ plane. On the other hand, at the horizontal region, the monolayers 500 are stacked on each other in the Z direction, and atoms at the monolayers 500 are connected to each other in an XY plane defined by the X and Y directions. With the provision of the insulating portions 32A, the first conductive lines 30A can be isolated from the subsequently formed conductive lines which are formed to alternate with the first conductive lines 30A.

In some embodiments, each of the first conductive lines 30A is covered by and prevented from being exposed from a respective one of the insulating portions 32A. Each of the first conductive lines 30A and the respective insulating portion 32A may be together referred to as an interconnecting unit 60. In some embodiments, as shown in FIG. 7, an upper surface of each of the first conductive lines 30A has a width W1 in the X direction, and an upper surface of the respective insulating portion 32A has a width W2 in the X direction. The width W2 is greater than the width W1.

In some embodiments, step S02 may include two sub-steps, which are sequentially shown in FIGS. 6 and 7.

Referring to FIG. 6, in the first sub-step, an insulating layer 320A is formed on the first conductive lines 30A, the underlying portions 31 and the base structure 9 by thermal CVD, PECVD, a transfer technique, or other suitable deposition techniques. The insulating layer 320A includes the material of the insulating portions 32A (see FIG. 7). Hence, the insulating layer 320A includes the monolayers 500 of the 2d conductive material.

Referring to FIG. 7, in the second sub-step, a patterning process is performed such that the insulating layer 320A (see FIG. 6) is formed into the insulating portions 32A and such that the portions of the base structure 9 (which are exposed from the underlying portions 31 and/or the first conductive lines 30A shown in FIG. 3) are partially exposed from the insulating portions 32A.

In some alternative embodiments, step S02 may include three sub-steps, which are sequentially shown in FIGS. 8, 9 and 10.

Referring to FIG. 8, in the first sub-step, self-assembled monolayers 33 are respectively formed on the portions of the base structure 9 which are exposed from the first conductive lines 30A (see FIG. 3), while exposing the first conductive lines 30A from the self-assembled monolayers 33. The self-assembled monolayers 33 serve as blocking layers to reduce, or even prevent, the 2d insulating material from being deposited thereon. In some embodiments, the self-assembled monolayers 33 are formed from precursor molecules each including a silicon-containing head group and a tail group. The tail group is connected to the head group and contains an organic chain, such as hydrocarbon chain, or the like. For example, the precursor molecules may be selected from hexamethyldisilazane (HMDS, which is represented by a chemical formula of (CH₃)₃SiNHSi(CH₃)₃), (dimethylamino)trimethylsilane (DMA-TMS, which is represented by a chemical formula of (CH₃)₃SiN(CH₃)₂), octadecyltrichlorosilane (ODTS, which is represented by a chemical formula of CH₃(CH₂)₁₇SiCl₃), other suitable precursor molecules, or combinations thereof. Each of the self-assembled monolayers 33 is prevented from being in contact with two corresponding adjacent ones of the first conductive lines 30A. In some embodiments, each of the self-assembled monolayers 33 has a first thickness, and each of the underlying portions 31 has a second thickness. The first thickness is less than the second thickness.

Referring to FIG. 9, in the second sub-step, the insulating portions 32A may be selectively formed on the first conductive lines 30A, respectively (for example, by thermal CVD, PECVD, or other suitable deposition techniques) while keeping the self-assembled monolayers 33 being exposed. This is because a deposition rate of 2d insulating material on the first conductive lines 30A is much greater than a deposition rate of 2d insulating material on the self-assembled monolayers 33.

Referring to FIG. 10, in the third sub-step, after forming the insulating portions 32A, the self-assembled monolayers 33 (see FIG. 9) are removed by an ashing process using a plasma, an ultraviolet-ozone (UV-O₃) treatment process, a thermal treatment process, or other techniques suitable for removing the self-assembled monolayers 33. In some embodiments, the plasma may include an oxygen plasma, or a mixture of hydrogen plasma and nitrogen plasma.

For purposes of simplicity and clarity, the following schematic views illustrates the structures obtained after step S02 of an embodiment of the method 1 (see the structure shown in FIG. 7), while schematic views of the structures obtained after step S02 of another embodiment of the method 1 (see the structure FIG. 10) are not illustrated.

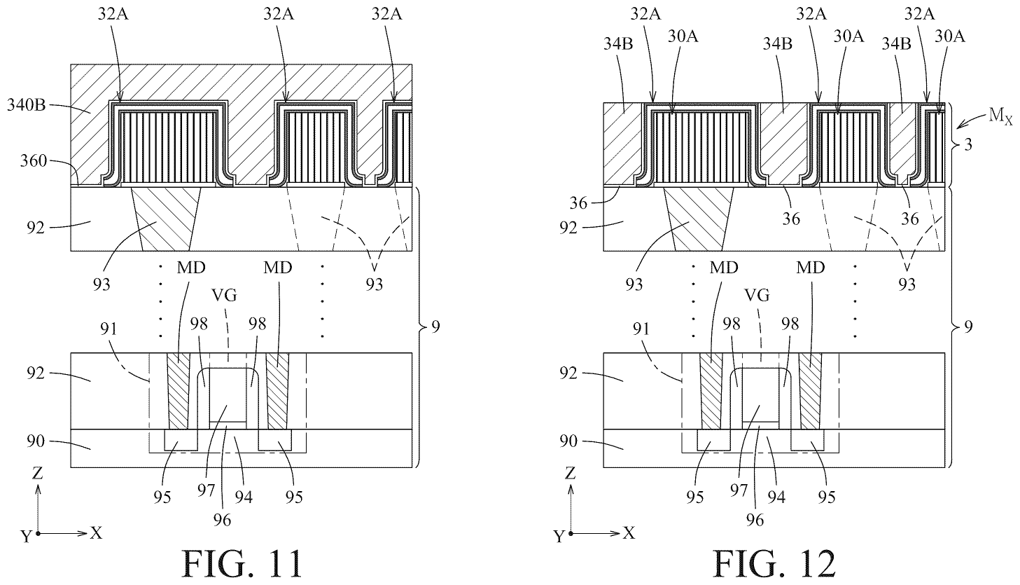

Referring to FIG. 1 and the example illustrated in FIG. 12, the method 1 proceeds to step S03, where second conductive lines 34B (which may be also referred to as second conductive portions) are respectively formed in the trenches 35 (see FIG. 7) such that the second conductive lines 34B are disposed to alternate with the first conductive lines 30A and such that each of the first conductive lines 30A is separated from two adjacent ones of the second conductive lines 34B through a respective one of the insulating portions 32A. FIG. 12 is a schematic sectional view similar to that of FIG. 7, but illustrating the structure after step S03 in accordance with some embodiments. After step S03, an Mₓ interconnecting layer 3 located at the metal level Mₓ is thus obtained. FIG. 11 is a schematic view illustrating a sub-step of step S03, in which the second conductive lines 34B shown in FIG. 12 are formed in accordance with some embodiments.

In some embodiments, each of the second conductive lines 34B includes a 3d conductive material. The 3d conductive material has a three-dimensional conducting path. That is, the electrical conductivity of each of the second conductive lines 34B is isotropic. The electrons (or current) in each of the second conductive lines 34B may freely travel in any direction. In some embodiments, the 3d conductive material includes a bulk metal or a bulk alloy. In some embodiments, metal elements suitable for forming the bulk metal (or the bulk alloy) includes Co, Cu, Ni, Ru, W, Mo, Ti, Zr, Ta, Zn, or alloys thereof.

In some embodiments, in step S03, liner portions 36 are formed prior to formation of the second conductive lines 34B. Each of the liner portions 36 is disposed to separate one of the second conductive lines 34B from the base structure 9 and two corresponding adjacent ones of the insulating portions 32A. In some embodiments, each of the liner portions 36 may be used to improve an adhesion of a respective one of the second conductive lines 34B to surrounding elements adjacent thereto. In some embodiments, each of the liner portions 36 may include Co, Al, Nb, Pb, Pt, Ni, Sc, Ru, Mo, W, Ir, Rh, or alloys thereof. Other possible materials suitable for the liner portions 36 are within the contemplated scope of the present disclosure. In some embodiments, each of the liner portions 36 may have a thickness ranging from about 0.3 nm to about 10 nm, but is not limited thereto. In some embodiments not shown herein, in step S03, diffusion barriers are formed prior to formation of the liner portions 36. The diffusion barriers are used to reduce current leakage which may be caused by out-diffusion of metal elements in each of the second conductive line 34B toward an adjacent one of the first conductive lines 30A. Each of the diffusion barriers is disposed between one of the liner portions 36 and a corresponding one of the insulating portions 32A. In some embodiments, each of the diffusion barriers may include TaN, Ta, Ti, TiN, or combinations thereof. Other possible materials suitable for the diffusion barriers are within the contemplated scope of the present disclosure.

In some embodiments, step S03 may include two sub-steps, which are sequentially shown in FIGS. 11 and 12.

Referring to FIG. 11, in the first sub-step, a liner layer 360 and a second conductive layer 340B are sequentially formed on the base structure 9 and the insulating portions 32A to fill the trenches 35 (see FIG. 7) by electrochemical plating, electroless deposition, CVD, PVD, ALD, or other suitable deposition techniques. The liner layer 360 and the second conductive layer 340B respectively include the materials of the liner portions 36 and the second conductive lines 34B.

Referring to FIG. 12, in the second sub-step, a removal process is performed to remove excess portions of the second conductive layer 340B (see FIG. 11) and the liner layer 360 (see FIG. 11) until the insulating portions 32A are exposed. After the removal process, the second conductive layer 340B is formed into the second conductive lines 34B, and the liner layer 360 is formed into the liner portions 36. In some embodiments, the removal process may include a planarization process such as chemical mechanical polishing. In some embodiments, processes parameters (e.g., process time, etc.) of the removal process are controlled so as not to expose the first conductive lines 30A. In other words, each of the first conductive lines 30A may remain being covered by a respective one of the insulating portions 32A without being exposed. In some embodiments, upper surfaces of the second conductive lines 34B are flush with an upper surface of the horizontal region of each of the insulating portions 32A. In some embodiments, the upper surfaces of the second conductive lines 34B are located at a level that is higher than a level of upper surfaces of the first conductive lines 30A. In some embodiments, a ratio of a width of the first conductive line 30A in the X direction to a width of each of the second conductive lines 34B in the X direction ranges from about 1:100 to about 100:1.

Referring to FIG. 1 and the example illustrated in FIG. 13, the method 1 proceeds to step S04, where a dielectric layer 38 is formed on the Mₓ interconnect layer 3. FIG. 13 is a schematic sectional view similar to that of FIG. 12, but illustrating the structure after step S04 in accordance with some embodiments.

In some embodiments, the dielectric layer 38 may include silicon oxide, silicon oxycarbide, silicon oxynitride, phosphosilicate glass (PSG), borosilicate glass (BSG), borophosphosilicate glass (BPSG), undoped silicate glass (USG), fluorinated silicate glass (FSG), silicon oxycarbide (SiOC), spin-on-glass (SOG), fluorine-doped silicon oxide, carbon-doped silicon oxide, porous silicon oxide, porous carbon-doped silicon oxide, other suitable low dielectric constant materials, or combinations thereof. Other possible materials suitable for the dielectric layer 38 are within the contemplated scope of the present disclosure.

In some embodiments, prior to formation of the dielectric layer 38, a nucleation layer 40 and an etching stop layer 37 are sequentially formed on the Mₓ interconnect layer 3, so as to permit the dielectric layer 38 to be subsequently formed on the etching stop layer 37. In some embodiments, the etching stop layer 37 may be made of a material that is different from the dielectric layer 38. Possible materials suitable for forming the etching stop layer 37 may include silicon nitride, silicon oxycarbide, silicon carbon nitride, aluminum oxide, aluminum nitride, aluminum oxynitride, other suitable metallic oxides, or combinations thereof. Other possible materials suitable for the etching stop layer 37 are within the contemplated scope of the present disclosure. In some embodiments, with the provision of the nucleation layer 40, the etching stop layer 37 may completely cover the second conductive lines 34B and the insulating portions 32A. In some embodiments, the nucleation layer 40 may include aluminum oxide, silicon oxycarbide, aluminum, or combinations thereof. Other possible materials suitable for the nucleation layer 40 are within the contemplated scope of the present disclosure. In some embodiments, the nucleation layer 40 may have a thickness ranging from about 0.3 nm to about 10 nm, but is not limited thereto. In some embodiments, each of the nucleation layer 40, the etching stop layer 37 and the dielectric layer 38 may be formed by ALD, CVD, PVD, or other suitable deposition techniques.

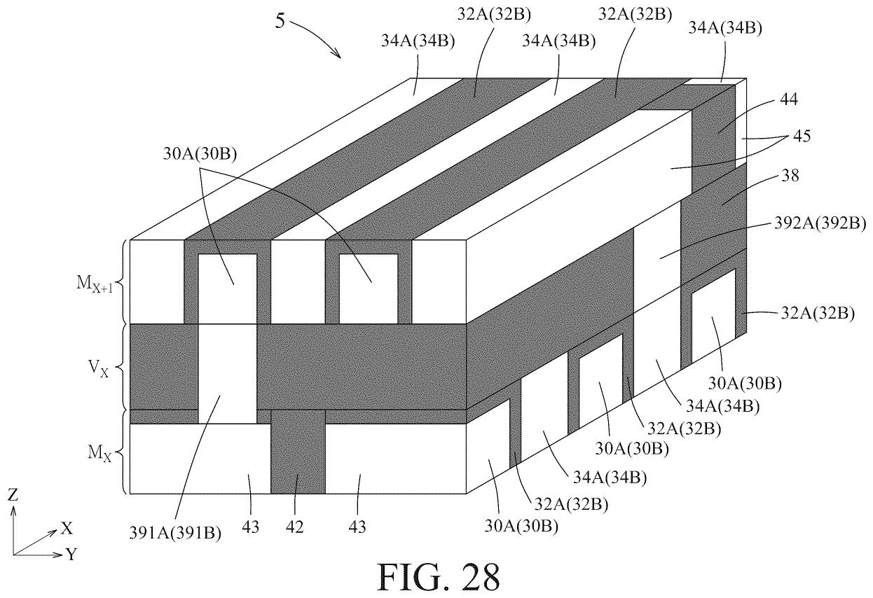

Referring to FIG. 1 and the example illustrated in FIG. 14, the method 1 proceeds to step S05, where first conductive vias 391B and second conductive vias 392B are formed in the dielectric layer 38, thereby obtaining a Vₓ interconnecting layer 4 located at a via level Vₓ, where x may be 0 or an integer not less than 1. The Vₓ interconnecting layer 4 is located between the Mₓ interconnecting layer 3 and an Mₓ₊₁ interconnecting layer (indicated by Mₓ₊₁ in FIG. 28). FIG. 14 is a schematic sectional view similar to that of FIG. 13, but illustrating the structure after step S05 in accordance with some embodiments.

As shown in FIG. 14, each of the first conductive vias 391B is connected to a corresponding one of the first conductive lines 30A, and each of the second conductive vias 392B is connected to a corresponding one of the second conductive lines 34B. The first and second conductive vias 391B, 392B are spaced apart from each other. In some embodiments, each of the first conductive vias 391B in the dielectric layer 38 further penetrates the etching stop layer 37, the nucleation layer 40 and a corresponding one of the insulating portions 32A, so as to be connected to the corresponding first conductive line 30A. Each of the second conductive vias 392B in the dielectric layer 38 further penetrates the etching stop layer 37 and the nucleation layer 40 so as to be connected to the corresponding second conductive line 34B. In some embodiments, a dimension in the X direction of each of the first and second conductive vias 391B, 392B may be smaller than, larger than, or substantially equal to the width in the X direction of a corresponding one of the first and second conductive lines 30A, 34B. Although two of the first conductive vias 391B and two of the second conductive vias 392B are exemplarily shown in FIG. 14, the number of the first and second conductive vias 391B, 392B may vary according to practical applications.

In some embodiments, as shown in FIG. 14, the first and second conductive vias 391B, 392B each includes a 3d conductive material. Possible 3d conductive materials suitable for forming the first and second conductive vias 391B, 392B may be similar to those for forming the second conductive lines 34B as described above with reference to FIG. 12. In some embodiments, formation of the first and second conductive vias 391B, 392B may include: forming via openings (not shown) in the dielectric layer 38 by a patterning process (e.g., a photolithography process) to expose the first and second conductive lines 30A, 34B; and forming the first and second conductive vias 391B, 392B respectively in the via openings using a deposition process (e.g., thermal CVD, PECVD, ALD, PVD, etc.) followed by a planarization process (e.g., chemical mechanical polishing). The first and second conductive vias 391B, 392B may be formed at the same time, or may be separately formed.

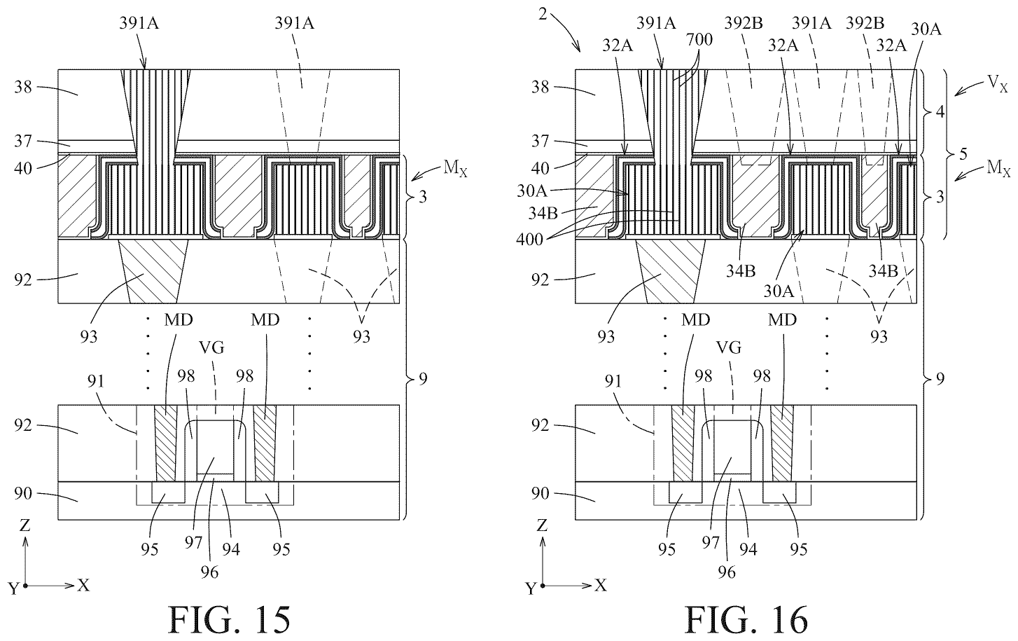

FIG. 16 illustrates a structure similar to that of FIG. 14 but the first conductive vias include or are made of a 2d conductive material and thus are denoted by numeral 391A. FIG. 15 is a schematic view illustrating a sub-step of step S05, in which the first and second conductive vias 391A, 392B shown in FIG. 16 are formed in accordance with some embodiments. Possible 2d conductive materials suitable for forming the first conductive vias 391A may be similar to those for forming the first conductive lines 30A as described above with reference to FIG. 3. The 2d conductive material of the first conductive vias 391A may be the same as or different from that of the first conductive lines 30A. In some embodiments, each of the first conductive vias 391A includes multiple monolayers 700 of the 2d conductive material. In some embodiments, the monolayers 700 in each of the first conductive vias 391A and the monolayers 400 located therebeneath are extended in substantially the same direction. In some embodiments, at least one of the monolayers 700 and a corresponding underlying one of the monolayers 400 may be connected to each other, thereby resulting in a better electron conduction.

In some embodiments, formation of the first and second conductive vias 391A, 392B shown in FIG. 16 may include two sub-steps, which are sequentially shown in FIGS. 15 and 16. In the first sub-steps, as shown in FIG. 15, the first conductive vias 391A are formed in the dielectric layer 38 in a manner similar to formation of the first conductive vias 391B as described above with reference to FIG. 14, except that the first conductive vias 391A may be formed before formation of the second conductive vias 392B (see FIG. 16). Formation of the first conductive vias 391A may include a deposition technique suitable for depositing the 2d conductive material as described above with reference to FIG. 2. In the second sub-step, as shown in FIG. 16, the second conductive vias 392B are formed the dielectric layer 38 in a manner similar to formation of the second conductive vias 392B as described above with reference to FIG. 14. In some alternative embodiments not shown herein, the first conductive vias 391A may be formed after formation of the second conductive vias 392B.

In some embodiments, some steps in the method 1 may be modified, replaced, or eliminated without departure from the spirit and scope of the present disclosure. In some alternative embodiments, the semiconductor structure 2 and the interconnecting structure 5 may further include additional features, and/or some features present in the semiconductor structure 2 and the interconnecting structure 5 may be modified, replaced, or eliminated without departure from the spirit and scope of the present disclosure.

In the following description, variants of the interconnecting structure 5 are provided to illustrate that the materials of the insulating portions, the first and second conductive lines, and the first and second conductive vias may be changed according to practical applications. Similar numerals indicated in the above-mentioned embodiments have been used where appropriate, with some construction differences being indicated with different numerals.

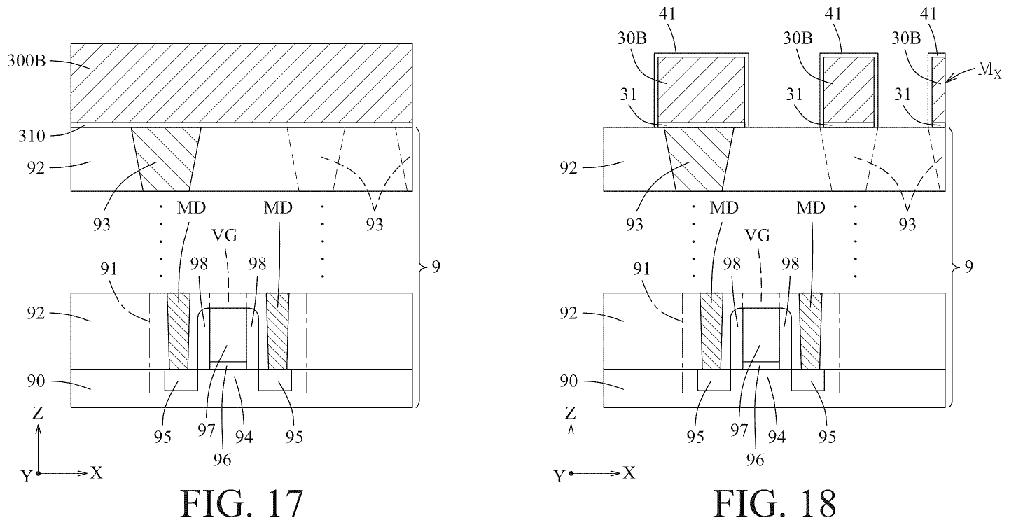

In some embodiments, the method 1 illustrated in FIG. 1 may include the intermediate stages shown in FIGS. 2 to 16 as described above, while in certain embodiments, the method 1 may include the intermediate stages shown in FIGS. 17 to 24 as described below.

Referring to FIG. 1 and the example illustrated in FIG. 18, the method 1 begins at step S01, where first conductive lines 30B are formed. FIG. 17 is a schematic view illustrating a sub-step of step S01, in which the first conductive lines 30B are formed in accordance with some embodiments.

The first conductive lines 30B shown in FIG. 18 may have a structure similar to that of the first conductive lines 30A shown in FIG. 3 except that the first conductive lines 30B include or are made of a 3d conductive material. Possible 3d conductive materials suitable for forming the first conductive lines 30B may be similar to those for forming the second conductive lines 34B as described above with reference to FIG. 12. In some embodiments, formation of the first conductive lines 30B may include two sub-steps. The first and second sub-steps of step S01 shown by FIGS. 17 and 18 are respectively similar to the first and second sub-steps shown by FIGS. 2 and 3 except that a conductive layer 300B for forming the first conductive lines 30B includes the material of the first conductive line 30B and the underlying layer 310 (which may be also referred to as an adhesion layer or a seed layer) may the same or different from that described above with reference to FIG. 2. For example, in the case that the first conductive lines 30B are made of Cu, the underlying portions 31 may be a Cu seed layer for growing Cu. Other possible materials suitable for the underlying layer 310 for growing the conductive layer 300B thereon are within the contemplated scope of the present disclosure. In some embodiments, after formation of the first conductive lines 30B and before proceeding to step S02 (formation of the insulating portions), diffusion barrier portions 41 may be further formed to respectively cover the first conductive lines 30B so as to prevent metal elements in the first conductive lines 30B from out-diffusion. Possible materials suitable for forming the diffusion barrier layers 41 may be similar to those for forming the diffusion barriers as described above with reference to FIG. 12. In some embodiments, each of the diffusion barrier portions 41 may have a thickness ranging from about 0.3 nm to about 10 nm, but is not limited thereto. In some embodiments, the diffusion barrier portions 41 may formed by a deposition process followed by a patterning process.

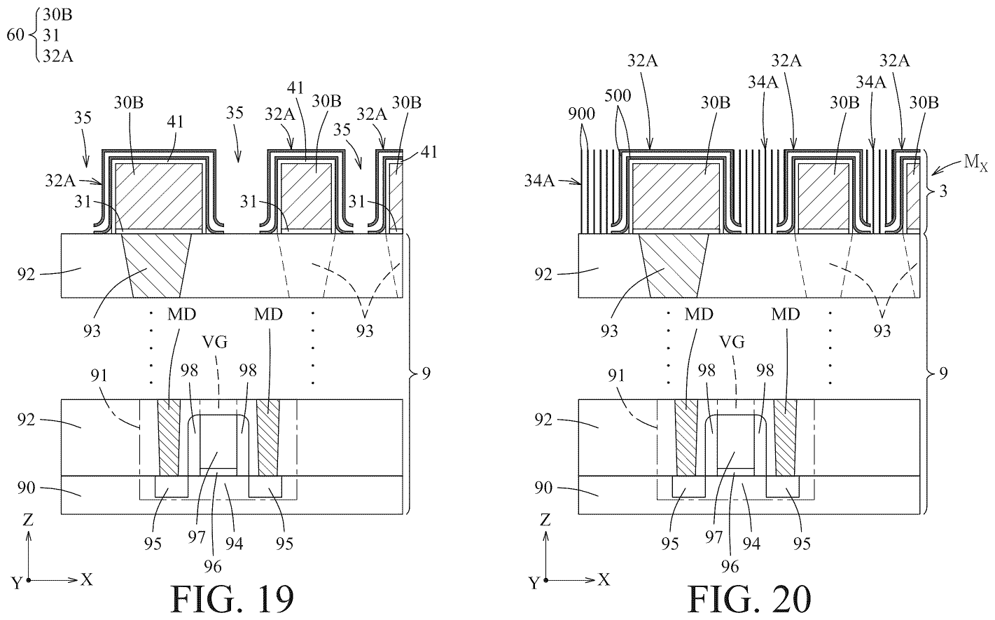

Referring to FIG. 1 and the examples illustrated in FIG. 19, the method 1 proceeds to step S02, where the insulating portions 32A are formed. Formation and configuration of the insulating portions 32A shown in FIG. 19 are similar to those as described above with reference to FIGS. 6 to 10, except that in FIG. 19, each of the diffusion barrier portions 41 is disposed between one of the insulating portions 32A and a corresponding one of the first conductive lines 30B.

Referring to FIG. 1 and the example illustrated in FIG. 20, the method 1 proceeds to step S03, where second conductive lines 34A are formed.

The second conductive lines 34A shown in FIG. 20 may have a structure similar to that of the second conductive lines 34B shown in FIG. 12 except that the second conductive lines 34A include or are made of a 2d conductive material. Possible 2d conductive materials suitable for forming the second conductive lines 34A may be similar to those for forming the first conductive lines 30A as described above with reference to FIG. 3. As shown in FIG. 20, each of the second conductive lines 34A may include multiple monolayers 900 of the 2d conductive material. In some embodiments, the monolayers 900 in each of the second conductive lines 34A may be arranged in a way similar to that of the monolayers 400 in each of the first conductive lines 30A shown in FIG. 3. As shown in FIG. 20, the monolayers 900 of the second conductive lines 34A are arranged substantially parallel to the monolayers 500 at the vertical regions of the insulating portions 32A.

In some embodiments, formation of the second conductive lines 34A may be performed in a manner similar to formation of the second conductive lines 34B as described above with reference to FIGS. 11 and 12, except that formation of the second conductive lines 34B may include a deposition technique suitable for depositing the 2d conductive material as described above with reference to FIG. 2. After formation of the second conductive lines 34A, each of the first conductive lines 30B may remain covered by a respective one of the insulating portions 32A without being exposed. In some embodiments, upper surfaces of the second conductive lines 34A are flush with the upper surface of the horizontal region of each of the insulating portions 32A. In some embodiments, the upper surfaces of the second conductive lines 34A are located at a level that is higher than a level of an upper surface of each of the first conductive lines 30B.

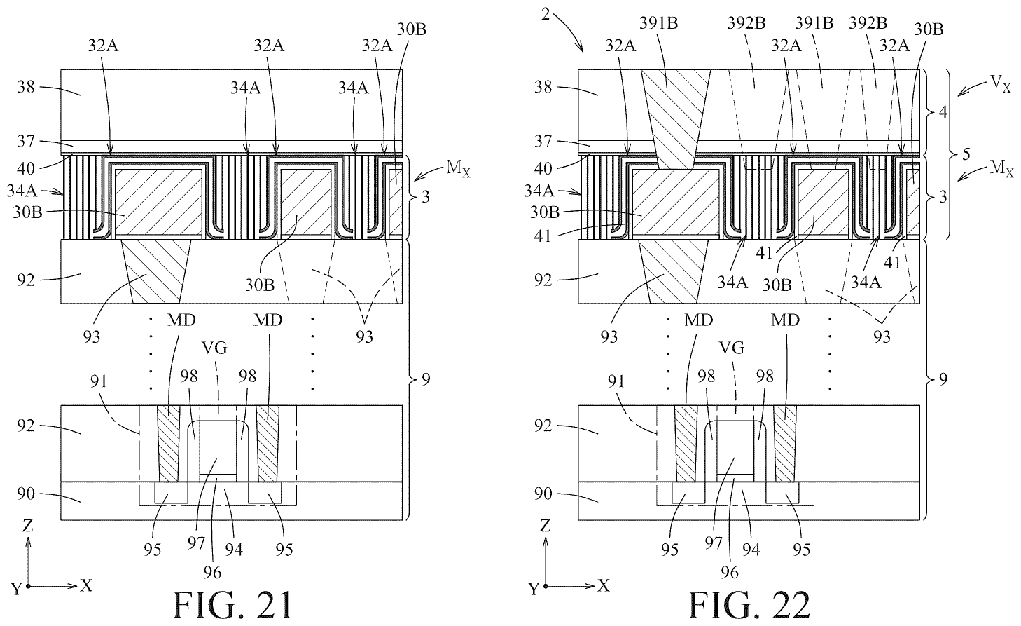

Referring to FIG. 1 and the example illustrated in FIG. 21, the method 1 proceeds to step S04, where the dielectric layer 38 is formed. Since formation and configuration of the dielectric layer 38 and the other elements 37, 40 shown in FIG. 19 are similar to those as described above with reference to FIG. 13, the details thereof are omitted for the sake of brevity.

Referring to FIG. 1 and the example illustrated in FIG. 22, the method 1 proceeds to step S05, where the first and second conductive vias 391B, 392B are formed.

Formation and configuration of the first and second conductive vias 391B, 392B shown in FIG. 22 are similar to those as described above with reference to FIG. 14, except that each of the first conductive vias 391B is connected to a corresponding one of the first conductive lines 30B, and each of the second conductive vias 392B is connected to a corresponding one of the second conductive lines 34A. In addition, each of the first conductive vias 391B in the dielectric layer 38 further penetrates a corresponding one of the diffusion barrier portions 41 so that each of the first conductive vias 391B is connected to the corresponding first conductive line 30B.

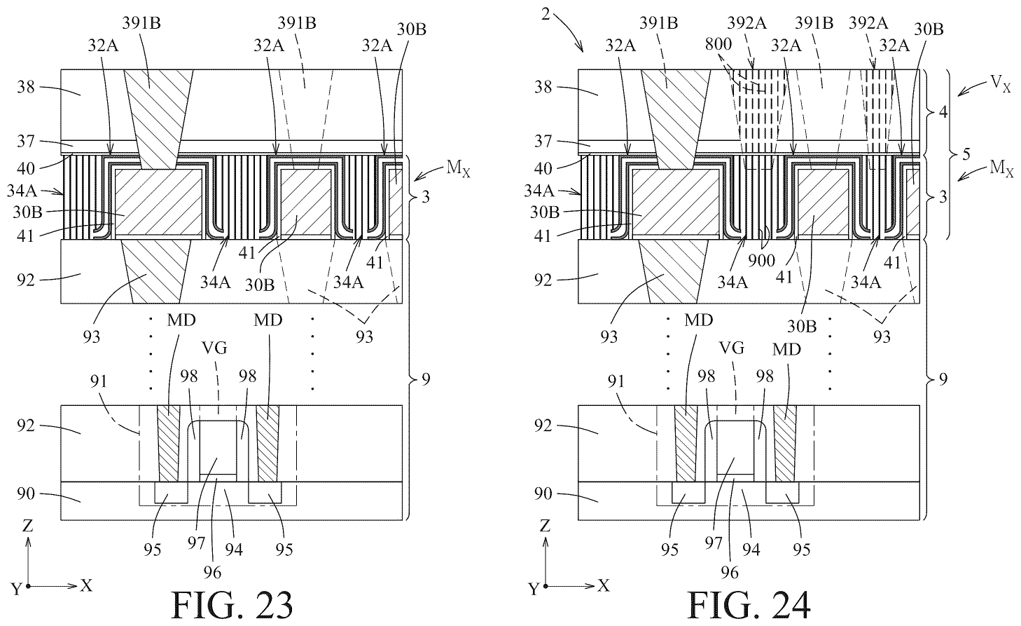

FIG. 24 illustrate a structure similar to that of FIG. 22 but the second conductive vias include or made of a 2d conductive material and thus are denoted by numeral 392A. FIG. 23 is a schematic view illustrating a sub-step of step S05, in which the first and second conductive vias 391B, 392A shown in FIG. 24 are formed in accordance with some embodiments. Possible 2d conductive materials suitable for forming the second conductive vias 392A may be similar to those for forming the second conductive lines 34A as described above with reference to FIG. 20. The 2d conductive material of the second conductive vias 392A may be the same as or different from that of the second conductive lines 34A. In some embodiments, each of the second conductive vias 392A includes multiple monolayers 800 of the 2d conductive material. In some embodiments, the monolayers 800 in each of the second conductive vias 392A and the monolayers 900 located therebeneath are extended in substantially the same direction. In some embodiments, at least one of the monolayers 800 and a corresponding underlying one of the monolayers 900 may be connected to each other, thereby resulting in a better electron conduction.

In some embodiments, formation of the first and second conductive vias 391B, 392A shown in FIG. 24 may include two sub-steps, which are sequentially shown in FIGS. 23 and 24. In the first sub-step, as shown in FIG. 23, the first conductive vias 391B may be performed in a manner similar to formation of the first conductive vias 391B as described above with reference to FIG. 22, except that the first conductive vias 391B may be formed before formation of the second conductive vias 392A (see FIG. 24). In the second sub-step, as shown in FIG. 24, the second conductive vias 392A are formed the dielectric layer 38 in a manner similar to formation of the second conductive vias 392B above with reference to FIG. 22, except that formation of the second conductive vias 392A may include a deposition technique suitable for depositing the 2d conductive material as described above with reference to FIG. 2. In some alternative embodiments not shown herein, the first conductive vias 391B may be formed after formation of the second conductive vias 392A.

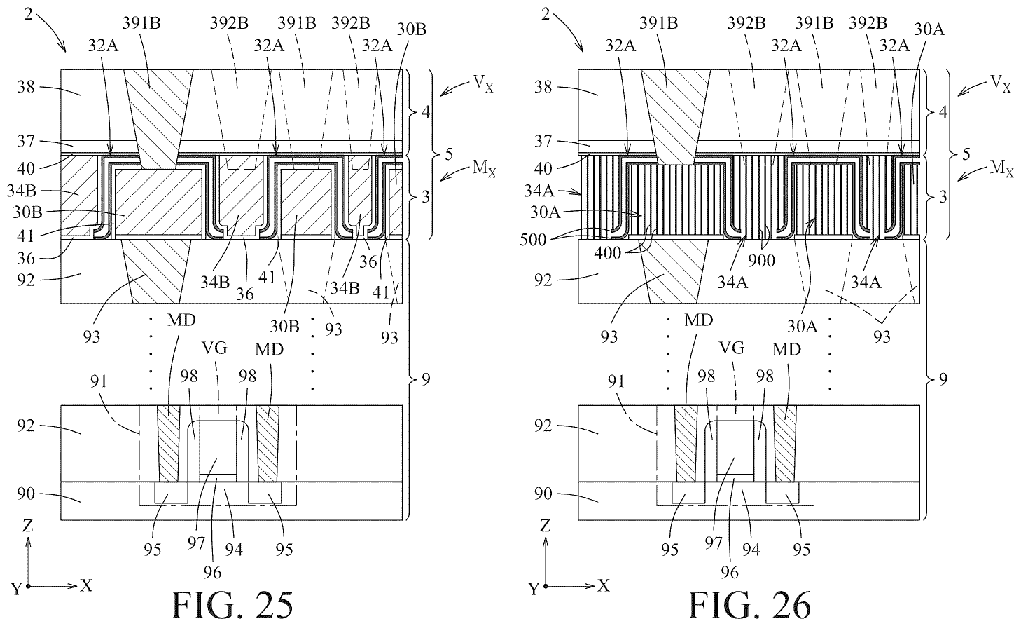

FIGS. 25 to 27 respectively illustrate different embodiments of the interconnecting structure 5 of the semiconductor structure 2.

The interconnecting structure 5 shown in FIG. 25 has a structure that is similar to that of the interconnecting structure 5 shown in FIG. 22, except that in the Mₓ interconnecting layer 3 shown in FIG. 25, both the first and second conductive lines shown in FIG. 25 include or are made of a 3d conductive material, and thus are denoted by numerals 30B and 34B, respectively. The 3d conductive material of the first conductive lines 30B may be the same as or different from that of the second conductive lines 34B. In addition, the Mₓ interconnecting layer 3 shown in FIG. 25 further includes the liner portions 36 as described above with reference to FIG. 12. Each of the liner portions 36 is disposed to separate one of the second conductive lines 34B from the base structure 9 and two corresponding adjacent ones of the insulating portions 32A.

The interconnecting structure 5 shown in FIG. 26 has a structure that is similar to that of the interconnecting structure 5 shown in FIG. 22, except that in the Mₓ interconnecting layer 3 shown in FIG. 26, both the first and second conductive lines . . . shown in FIG. 26 include or are made of a 2d conductive material, and thus are denoted by numerals 30A and 34A, respectively. In addition, in the Mₓ interconnecting layer 3 shown in FIG. 26, each of the first conductive lines 30A may be in direct contact with a respective one of the insulating portions 32A.

Although in some embodiments the first and second conductive vias 391B, 392B in the Vₓ interconnecting layer 4 shown in FIG. 26 include or are made of a 3d conductive material, in some other embodiments, the first and second conductive vias may include or be made of a 2d conductive material (such as the examples as described above with reference to FIGS. 16 and 24). In such case, monolayers in each of the first conductive vias and the monolayers 400 located therebeneath are extended in substantially the same direction, and monolayers in each of the second conductive vias and the monolayers 900 located therebeneath are extended in substantially the same direction. In some embodiments, at least one of the monolayers in the Vₓ interconnecting layer 4 and a corresponding underlying one of the monolayers 400, 900 may be connected to each other, thereby resulting in a better electron conduction.

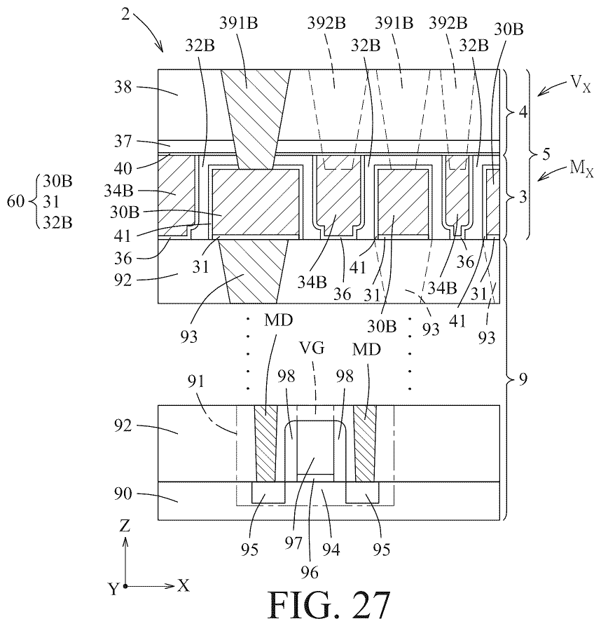

The interconnecting structure 5 shown in FIG. 27 has a structure that is similar to that of the interconnecting structure 5 shown in FIG. 25, except that in the Mₓ interconnecting layer 3, the insulating portions (i.e., the elements 32B) shown in FIG. 27 are each made of a dielectric material. Possible dielectric materials suitable for forming the insulating portions 32B may be similar to those for forming the dielectric layer 38 as described above with reference to FIG. 13. Formation of the insulating portions 32B may be performed in a manner similar to formation of the insulating portions 32A, and thus the details thereof are omitted for the sake of brevity.

FIG. 28 is a schematic perspective view illustrating the interconnecting structure 5 in accordance with some embodiments. The interconnecting structure 5 shown in FIG. 28 has a structure similar to that of the interconnecting structure 5 shown in FIG. 14, 16, 22, 24, 25, 26, or 27, but FIG. 28 schematically illustrates, without being drawn to scale, (i) the first conductive lines 30A or 30B and the second conductive lines 34A or 34B in the Mₓ interconnecting layer, and (ii) the dielectric layer 38, the first conductive vias 391A or 391B and the second conductive vias 392A or 392B in the Vₓ interconnecting layer, while other elements are omitted. In addition, the interconnecting structure 5 shown in FIG. 28 further includes (iii) an Mₓ₊₁ interconnecting layer formed on the Vₓ interconnecting layer opposite to the Mₓ interconnecting layer. The Mₓ₊₁ interconnecting layer has a structure similar to that of the Mₓ interconnecting layer, but the first and second conductive lines in the Mₓ₊₁ interconnecting layer are elongated in a direction transverse to an elongated direction of the first and second conductive lines in the Mₓ interconnecting layer.

In some embodiments, the interconnecting structure 5 further includes dielectric portions 42, 44 (two of which are exemplarily shown in FIG. 28). Each of the dielectric portions 42, 44 is used to cut a corresponding one of the conductive lines 30A (or 30B), 34A (or 34B). In some embodiments, the dielectric portion 42 may be formed in the Mₓ interconnecting layer so as to separate a frontmost one of the first conductive lines 30A (or 30B), which are elongated in the Y direction, into two first line segments 43. The two first line segments 43 are respectively located at two opposite sides of the dielectric portion 42 in the Y direction. In some embodiments, the dielectric portion 44 may be formed in the Mₓ₊₁ interconnecting layer so as to separate a rightmost one of the second conductive lines 34A (or 34B), which are elongated in the X direction, into two second line segments 45. The two second line segments 45 are respectively located at two opposite sides of the dielectric portion 44 in the X direction.

Possible materials suitable for forming the dielectric portions 42, 44 are similar to those for forming the dielectric layer 38 as describe above with reference to FIG. 13, and thus the details are omitted for the sake of brevity. In some embodiments, each of the dielectric portion 42 may be formed by a patterning process (e.g., a lithography process) and a suitable deposition process. Formation of the dielectric portion 42 may be performed after formation of the second conductive lines 34A (or 34B) at the Mₓ interconnecting layer and before formation of the dielectric layer 38 at the Vₓ interconnecting layer. Formation of the dielectric portion 44 may be performed after formation of the second conductive lines 34A (or 34B) at the Mₓ₊₁ interconnecting layer and before formation of a dielectric layer (not shown) at a Vₓ₊₁ interconnecting layer which will be formed on the Mₓ₊₁ interconnecting layer.

In summary, the interconnecting structure 5 manufactured by the method 1 has the following advantages. Since the insulating portions 32A are formed after formation of the first conductive lines 30A (or 30B) and before formation of the second conductive lines 34A (or 34B), and since the insulating portions 32A may be made of a 2d insulating material, a distance between each of the first conductive lines 30A (or 30B) and a corresponding adjacent one of the second conductive lines 34A (or 34B) in the Mₓ interconnecting layer may be minimized by controlling the thickness of the 2d insulating material. In addition, in the case that the first conductive lines 30A (and/or the second conductive lines 34A) are made of a 2d conductive material, the monolayers 500 of the 2d insulating material in each of the insulating portions 32A (in particular the vertical regions of each of the insulating portions 32A) may be stacked on the monolayers 400 (and/or 900) of the 2d conductive material (i.e., forming a heterogeneous stacked structure) in an adjacent one of the first conductive lines 30A (and/or the second conductive lines 34A) in the X direction. With the provision of a 2d hetero-structure including the monolayers 400, 500 (and/or 900), the density of electrical conductive paths in the Mₓ interconnecting layer may be significantly increased, and current leakage between each of the first conductive lines 30A (or 30B) and a corresponding adjacent one of the second conductive lines 34B (or 34A) may be effectively reduced.

In accordance with some embodiments of the present disclosure, a method for manufacturing an interconnecting structure includes: forming first conductive portions on a base structure, the first conductive portions being spaced apart from each other; after forming the first conductive portions, forming insulating portions which are spaced apart from each other to respectively cover the first conductive portions; and after forming the insulating portions, forming second conductive portions on the base structure such that the second conductive portions are disposed to alternate with the first conductive portions and such that each of the first conductive portions is separated from two adjacent ones of the second conductive portions through a respective one of the insulating portions.

In accordance with some embodiments of the present disclosure, the insulating portions include a two-dimensional insulating material, and each of the insulating portions includes at least one monolayer of the two-dimensional insulating material. A number of the at least one monolayer ranges from 1 to 100.

In accordance with some embodiments of the present disclosure, the two-dimensional insulating material includes hexagonal boron nitride, two-dimensional hafnium oxide, two-dimensional CaF₂, or combinations thereof.

In accordance with some embodiments of the present disclosure, formation of the insulating portions includes forming an insulating layer on the first conductive portions and the base structure, and patterning the insulating layer into the insulating portions.

In accordance with some embodiments of the present disclosure, formation of the insulating portions includes selectively forming blocking layers respectively on portions of the base structure which are exposed from the first conductive portions, while exposing the first conductive portions from the blocking layers; after selectively forming the blocking layers, forming the insulating portions to respectively cover the first conductive portions; and after forming the insulating portions, removing the blocking layers.

In accordance with some embodiments of the present disclosure, the blocking layers are formed from precursor molecules each including a silicon-containing head group and a tail group which is connected to the silicon-containing head group and which includes an organic chain.

In accordance with some embodiments of the present disclosure, the first conductive portions include a two-dimensional conductive material selected from graphene, two-dimensional metal, two-dimensional alloy, two-dimensional transition metal dichalcogenide, or combinations thereof, and the second conductive portions include Co, Cu, Ni, Ru, W, Mo, Ti, Zr, Ta, Zn, or alloys thereof.

In accordance with some embodiments of the present disclosure, the method further includes forming underlying portions on the base structure such that the first conductive portions are formed on the underlying portions, respectively. The underlying portions includes the titanium nitride, silicon, Bi₂Te₃, SiC, or Pd.

In accordance with some embodiments of the present disclosure, the first conductive portions include Co, Cu, Ni, Ru, W, Mo, Ti, Zr, Ta, Zn, or alloys thereof, and the second conductive portions include a two-dimensional conductive material selected from graphene, two-dimensional metal, two-dimensional alloy, two-dimensional transition metal dichalcogenide, or combinations thereof.

In accordance with some embodiments of the present disclosure, before forming the insulating portions, the method further includes selectively forming diffusion barrier portions to respectively cover the first conductive portions such that portions of the base structure are exposed from the diffusion barrier portions. The diffusion barrier portions includes Ti, TiN, Ta, TaN, or combinations thereof. The insulating portions are formed on the diffusion barrier portions, respectively, so as to cover the first conductive portions, respectively.

In accordance with some embodiments of the present disclosure, after formation of the insulation portions, trenches are formed to alternate with the insulation portions. Formation of the second conductive portions includes forming a conductive layer on the insulating portions to fill the trenches, and performing a removal process to expose the insulating portions such that the conductive layer is formed into the second conductive portions.

In accordance with some embodiments of the present disclosure, upper surfaces of the second conductive portions are located at a level that is higher than a level of an upper surface of each of the first conductive portions.

In accordance with some embodiments of the present disclosure, a method for manufacturing an interconnecting structure includes: forming first conductive lines on a base structure, the first conductive lines being elongated in a Y direction and spaced apart from each other in an X direction transverse to the Y direction; forming lower insulating portions which are spaced apart from each other to respectively cover the first conductive lines, the lower insulating portions including a first two-dimensional material; forming second conductive lines on the base structure such that the second conductive lines are disposed to alternate with the first conductive lines in the X direction and such that each of the first conductive lines is separated from two adjacent ones of the second conductive lines through a respective one of the lower insulating portions; forming an upper insulating portion to cover the lower insulating portions and the second conductive lines; forming first conductive vias in the upper insulating portion to respectively penetrate through the lower insulating portions so that the first conductive vias are respectively connected to the first conductive lines; and forming second conductive vias in the upper insulating portion so that the second conductive vias are respectively connected to the second conductive lines.

In accordance with some embodiments of the present disclosure, the first conductive lines or the second conductive lines include a second two-dimensional material which is different from the first two-dimensional material, the second two-dimensional conductive material including monolayers being stacked on each other in the X direction, atoms of each of the monolayers being connected to each other in an XZ plane defined by the X direction and a Z direction transverse to both the X direction and the Y direction.

In accordance with some embodiments of the present disclosure, each of the first conductive lines and the first conductive vias includes a second two-dimensional material which is different from the first two-dimensional material, and which includes graphene, two-dimensional metal, two-dimensional alloy, two-dimensional transition metal dichalcogenide, or combinations thereof, and each of the second conductive lines and the second conductive vias includes Co, Cu, Ni, Ru, W, Mo, Ti, Zr, Ta, Zn, or alloys thereof.

In accordance with some embodiments of the present disclosure, each of the first conductive lines and the first conductive vias includes Co, Cu, Ni, Ru, W, Mo, Ti, Zr, Ta, Zn, or alloys thereof, and each of the second conductive lines and the second conductive vias includes a second two-dimensional material which is different from the first two-dimensional material, and which includes graphene, two-dimensional metal, two-dimensional alloy, two-dimensional transition metal dichalcogenide, or combinations thereof.

In accordance with some embodiments of the present disclosure, the method further includes forming a dielectric portion in a corresponding one of the second conductive lines so as to separate the corresponding one of the second conductive lines into two line segments.

In accordance with some embodiments of the present disclosure, a semiconductor structure includes: a base structure; interconnecting units spaced apart from each other, each of the interconnecting units including a first conductive line disposed on the base structure, and an insulating layer which covers the first conductive line so as to prevent the first conductive line from being exposed from the insulating layer, and which includes a two-dimensional insulating material; and second conductive lines disposed on the base structure to alternate with the interconnecting units.

In accordance with some embodiments of the present disclosure, the second conductive lines are disposed to alternate with the interconnecting units in an X direction. A ratio of a width of the first conductive line in the X direction to a width of each of the second conductive lines in the X direction ranges from 1:100 to 100:1.

In accordance with some embodiments of the present disclosure, upper surfaces of the interconnecting units are flush with an upper surface of each of the second conductive portions.

In accordance with some embodiments of the present disclosure, a method for manufacturing a semiconductor structure includes: forming interconnecting units on a base structure, the interconnecting units being spaced apart from each other, each of the interconnecting units including a first conductive line formed on the base structure, and an insulating layer formed to cover the first conductive line so as to prevent the first conductive line from being exposed from the insulating layer, the insulating layer including a two-dimensional insulating material; and forming second conductive lines on the base structure such that the second conductive lines are formed to alternate with the interconnecting units.

In accordance with some embodiments of the present disclosure, the second conductive lines are formed to alternate with the interconnecting units in an X direction. A ratio of a width of the first conductive line in the X direction to a width of each of the second conductive lines in the X direction ranges from 1:100 to 100:1.

In accordance with some embodiments of the present disclosure, upper surfaces of the interconnecting units are flush with an upper surface of each of the second conductive portions.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing an interconnecting structure, comprising:
forming first conductive portions on a base structure, the first conductive portions being spaced apart from each other;
after forming the first conductive portions, forming insulating portions which are spaced apart from each other to respectively cover the first conductive portions; and
after forming the insulating portions, forming second conductive portions on the base structure such that the second conductive portions are disposed to alternate with the first conductive portions and such that each of the first conductive portions is separated from two adjacent ones of the second conductive portions through a respective one of the insulating portions.

2. The method as claimed in claim 1, wherein
the insulating portions include a two-dimensional insulating material, and
each of the insulating portions includes at least one monolayer of the two-dimensional insulating material, a number of the at least one monolayer ranging from 1 to 100.

3. The method as claimed in claim 2, wherein the two-dimensional insulating material includes hexagonal boron nitride, two-dimensional hafnium oxide, two-dimensional CaF₂, or combinations thereof.

4. The method as claimed in claim 2, wherein formation of the insulating portions includes forming an insulating layer on the first conductive portions and the base structure, and patterning the insulating layer into the insulating portions.

5. The method as claimed in claim 2, wherein formation of the insulating portions includes selectively forming blocking layers respectively on portions of the base structure which are exposed from the first conductive portions, while exposing the first conductive portions from the blocking layers,
after selectively forming the blocking layers, forming the insulating portions to respectively cover the first conductive portions, and
after forming the insulating portions, removing the blocking layers.

6. The method as claimed in claim 5, wherein the blocking layers are formed from precursor molecules each including a silicon-containing head group and a tail group which is connected to the silicon-containing head group and which includes an organic chain.

7. The method as claimed in claim 1, wherein
the first conductive portions include a two-dimensional conductive material selected from graphene, two-dimensional metal, two-dimensional alloy, two-dimensional transition metal dichalcogenide, or combinations thereof, and
the second conductive portions include Co, Cu, Ni, Ru, W, Mo, Ti, Zr, Ta, Zn, or alloys thereof.

8. The method as claimed in claim 7, further comprising forming underlying portions on the base structure such that the first conductive portions are formed on the underlying portions, respectively, the underlying portions including the titanium nitride, silicon, Bi₂Te₃, SiC, or Pd.

9. The method as claimed in claim 1, wherein
the first conductive portions include Co, Cu, Ni, Ru, W, Mo, Ti, Zr, Ta, Zn, or alloys thereof, and
the second conductive portions include a two-dimensional conductive material selected from graphene, two-dimensional metal, two-dimensional alloy, two-dimensional transition metal dichalcogenide, or combinations thereof.

10. The method as claimed in claim 1, wherein
before forming the insulating portions, the method further comprises selectively forming diffusion barrier portions to respectively cover the first conductive portions such that portions of the base structure are exposed from the diffusion barrier portions, the diffusion barrier portions including Ti, TiN, Ta, TaN, or combinations thereof, and
the insulating portions are formed on the diffusion barrier portions, respectively, so as to cover the first conductive portions, respectively.

11. The method as claimed in claim 1, wherein
after formation of the insulation portions, trenches are formed to alternate with the insulation portions, and
formation of the second conductive portions includes
forming a conductive layer on the insulating portions to fill the trenches, and
performing a removal process to expose the insulating portions such that the conductive layer is formed into the second conductive portions.

12. The method as claimed in claim 1, wherein upper surfaces of the second conductive portions are located at a level that is higher than a level of an upper surface of each of the first conductive portions.

13. A method for manufacturing an interconnecting structure, comprising:
forming first conductive lines on a base structure, the first conductive lines being elongated in a Y direction and spaced apart from each other in an X direction transverse to the Y direction;
forming lower insulating portions which are spaced apart from each other to respectively cover the first conductive lines, the lower insulating portions including a first two-dimensional material;
forming second conductive lines on the base structure such that the second conductive lines are disposed to alternate with the first conductive lines in the X direction and such that each of the first conductive lines is separated from two adjacent ones of the second conductive lines through a respective one of the lower insulating portions;
forming an upper insulating portion to cover the lower insulating portions and the second conductive lines;
forming first conductive vias in the upper insulating portion to respectively penetrate through the lower insulating portions so that the first conductive vias are respectively connected to the first conductive lines; and
forming second conductive vias in the upper insulating portion so that the second conductive vias are respectively connected to the second conductive lines.

14. The method as claimed in claim 13, wherein the first conductive lines or the second conductive lines include a second two-dimensional material which is different from the first two-dimensional material, the second two-dimensional conductive material including monolayers being stacked on each other in the X direction, atoms of each of the monolayers being connected to each other in an XZ plane defined by the X direction and a Z direction transverse to both the X direction and the Y direction.

15. The method as claimed in claim 13, wherein
each of the first conductive lines and the first conductive vias includes a second two-dimensional material which is different from the first two-dimensional material, and which includes graphene, two-dimensional metal, two-dimensional alloy, two-dimensional transition metal dichalcogenide, or combinations thereof, and
each of the second conductive lines and the second conductive vias includes Co, Cu, Ni, Ru, W, Mo, Ti, Zr, Ta, Zn, or alloys thereof.

16. The method as claimed in claim 13, wherein
each of the first conductive lines and the first conductive vias includes Co, Cu, Ni, Ru, W, Mo, Ti, Zr, Ta, Zn, or alloys thereof, and
each of the second conductive lines and the second conductive vias includes a second two-dimensional material which is different from the first two-dimensional material, and which includes graphene, two-dimensional metal, two-dimensional alloy, two-dimensional transition metal dichalcogenide, or combinations thereof.

17. The method as claimed in claim 13, further comprising forming a dielectric portion in a corresponding one of the second conductive lines so as to separate the corresponding one of the second conductive lines into two line segments.

18. A semiconductor structure, comprising:
a base structure;
interconnecting units spaced apart from each other, each of the interconnecting units including
a first conductive line disposed on the base structure, and
an insulating layer which covers the first conductive line so as to prevent the first conductive line from being exposed from the insulating layer, and which includes a two-dimensional insulating material; and
second conductive lines disposed on the base structure to alternate with the interconnecting units.

19. The semiconductor structure as claimed in claim 18, wherein the second conductive lines are disposed to alternate with the interconnecting units in an X direction, a ratio of a width of the first conductive line in the X direction to a width of each of the second conductive lines in the X direction ranging from 1:100 to 100:1.

20. The semiconductor structure as claimed in claim 18, wherein upper surfaces of the interconnecting units are flush with an upper surface of each of the second conductive portions.
